(19) United States
(12) Patent Application Publication
(10) Pub. No.: US 2026/0114189 A1
(43) Pub. Date: Apr. 23, 2026

(54) SELECTOR DEVICE, METHOD OF MANUFACTURING THE SAME AND MEMORY DEVICE INCLUDING SELECTOR DEVICE

(71) Applicants: SK Hynix Inc., Icheon-si (KR); UIF (UNIVERSITY INDUSTRY FOUNDATION), YONSEI UNIVERSITY, Seoul (KR)

(72) Inventors: MYOUNGSUB KIM, Icheon-si (KR); Taeyoon LEE, Seoul (KR); Minkyu LEE, Seoul (KR); Seungmin LEE, Seoul (KR); Jinhan LEE, Seoul (KR)

(21) Appl. No.: 19/359,502

(22) Filed: Oct. 15, 2025

(30) Foreign Application Priority Data
Oct. 17, 2024 (KR) 10-2024-0142328

(51) Int. Cl. H10N 70/00; H10B 63/00

(52) U.S. Cl. CPC H10N 70/8416; H10B 63/24; H10B 63/84; H10N 70/826; H10N 70/8822

(57) ABSTRACT

An OTS selector device may include a first electrode, a second electrode spaced apart from the first electrode and including a (W₂N)₁₋ₓCₓ material layer, x being in a range of about 0.11 to about 0.25, and an OTS material layer disposed between the first electrode and the second electrode, the OTS material layer including a chalcogenide element.

### CROSS-REFERENCE TO RELATED APPLICATION

The present application claims, under 35 U.S.C. § 119(a), the benefit of Korean Patent Application No. 10-2024-0142328, filed on Oct. 17, 2024, the entire disclosure of which is incorporated hereby by reference in its entirety.

### BACKGROUND

### 1. Field

Embodiments of the present disclosure relate to electronic devices and semiconductor device technology, and more particularly to a selector device (or selection/selective element), a method for manufacturing the selector device, and a memory device comprising the selector device.

### 2. Description of the Related Art

Next-generation memories based on resistance changes, such as resistive random access memory (ReRAM), phase-change RAM (PCRAM), and magnetic RAM (MRAM), have non-volatile characteristics that can significantly reduce power consumption, and have the advantages of high speed and high reliability. In addition, their simple structure enables high integration compared to conventional NAND flash memory, and when manufactured in a crossbar array structure, 4F2's design rules can be used to realize large memory devices.

In a crossbar array structure memory, memory cells are located at the intersection of word lines and bit lines. During the read/write process of a memory with a parallel structure, sneak currents generated by unselected cells during the read/write process can cause issues such as reading errors, reducing the sensing margin, and limiting the maximum size (capacity) of the memory that can be integrated. To address this leakage current issue, it is desirable to apply a selector device to the memory cell array. Various devices such as PN diodes, ovonic threshold switches (OTS), mixed ionic electronic conduction (MIEC) devices, field assisted super linear threshold (FAST) devices, metal-insulator transition (MIT) devices, and tunnel barrier diodes have been proposed as such selector devices.

In conventional selector devices, a degree of integration may be relatively low and performance may be deteriorated under repeated operation. In addition, the manufacturing of non-volatile memory array devices continues to require the development of technologies that can improve performance and density while lowering manufacturing costs and simplifying the manufacturing process.

### SUMMARY

According to embodiments of the present disclosure an ovonic threshold switch (OTS) selective device, which includes an electrode material that may compensate for and overcome the disadvantages of ovonic threshold switch (OTS) material layers containing chalcogenide elements, is provided.

Furthermore, according to embodiments of the present disclosure an OTS selective element, which includes an electrode material and an OTS material layer bonded thereto that may be applied to highly integrated devices and maintain good performance under repeated operation, is provided.

Further, according to embodiments of the present disclosure, a memory device that may improve performance and integration while lowering manufacturing costs and simplifying the manufacturing process by applying the above-mentioned OTS selective elements is provided.

Furthermore, according to embodiments of the present disclosure, a method of manufacturing the above-mentioned OTS selective element and memory element is provided.

Various aspects of embodiments of the present disclosure are not limited to those mentioned above, and other aspects may be understood by those skilled in the art from the following description.

According to an embodiment of the present disclosure, an ovonic threshold switch (OTS) selective element includes: a first electrode; a second electrode spaced apart from the first electrode, including a (W₂N)₁₋ₓCₓ material layer, wherein x is in the range of 0.11 to 0.25; and an OTS material layer disposed between the first electrode and the second electrode, including a chalcogenide element.

According to another embodiment of the present disclosure, there is provided a memory element including the aforementioned OTS selector device.

According to embodiments of the present disclosure, it is possible to realize an OTS selective device with an electrode material that may complement and resolve the disadvantages of an OTS material layer including a chalcogenide element. Furthermore, according to embodiments of the present disclosure, it is possible to realize an OTS selective device including an electrode material and an OTS material layer bonded thereto that may be applied to a highly integrated device and maintain desirable performance even in repeated operation. Furthermore, according to embodiments of the present disclosure, by applying the above OTS selective element, a memory device may be realized that may improve performance and integration while lowering manufacturing costs and simplifying manufacturing processes.

According to an embodiment, by preparing a (W₂N)₁₋ₓCₓ material film as an electrode of an OTS selective device and bonding it to an OTS material layer including a chalcogenide element (e.g., a GeS₂ layer), an OTS selective device may be realized that may lower the driving voltage and minimize power consumption by increasing the work function of the electrode and controlling the interface trap density between the electrode and the OTS material layer. Furthermore, by effectively suppressing the diffusion of the electrode material even in repeated operation, an OTS selective element having desirable durability/stability and long lifetime may be realized. By applying the OTS selector device according to an embodiment, a memory element (non-volatile memory element) having a selector-only memory (SOM) structure, for example, may be implemented, thereby improving the performance and integration of the memory element while lowering the manufacturing cost and simplifying the manufacturing process.

However, the effects of the present disclosure are not limited to the above-described effects, and other effects may be possible.

### BRIEF DESCRIPTION OF THE DRAWINGS

FIG. 1 is a cross-sectional view illustrating an ovonic threshold switch (OTS) selector device according to an embodiment of the present disclosure.

FIG. 2 is a cross-sectional view illustrating an OTS selector device according to another embodiment of the present disclosure.

FIG. 3 is a cross-sectional view illustrating an OTS selector device according to another embodiment of the present disclosure.

FIG. 4 is a cross-sectional view illustrating an OTS selector device manufactured in accordance with an embodiment of the present disclosure.

FIG. 5 is a graph showing the results of measuring the change in electrical characteristics of an OTS selective element according to an embodiment of the present disclosure in response to an increase in the carbon content of a (W₂N)₁₋ₓCₓ material layer applied as a second electrode in the OTS selective element.

FIG. 6 is a graph showing the results of evaluating the changes in subthreshold slope (STS), distance between traps (Δz), and interface trap density (Nᵢₜ) with increasing carbon content of the (W₂N)₁₋ₓCₓ material layer applied as the second electrode in an OTS selective element according to an embodiment of the present disclosure.

FIG. 7 shows the work function (WF) of a W₂N thin film and an amorphous carbon (a-C) thin film.

FIG. 8 shows the change in the work function (WF) as the carbon content of the (W₂N)₁₋ₓCₓ material layer increases.

FIGS. 9 and 10 are diagrams showing the variation of the energy band diagram as a function of the work function of the electrodes in interconnected electrodes and GeS₂ thin films.

FIG. 11 is an X-ray diffraction (XRD) graph illustrating the change in crystal properties as the carbon content of a (W₂N)₁₋ₓCₓ material layer varies, which may be applicable to an OTS selective element according to embodiments of the present disclosure.

FIG. 12 is a transmission electron microscope (TEM) analysis image illustrating the change in crystalline properties as the carbon content of a (W₂N)₁₋ₓCₓ material layer varies, which may be applied to an OTS selective element according to embodiments of the present disclosure.

FIG. 13 is a graph illustrating the change in resistivity as the carbon content of a (W₂N)₁₋ₓCₓ material layer varies, which may be applied to an OTS selector device according to an embodiment of the present disclosure.

FIG. 14 is a graph illustrating the change in density with change in carbon content of a (W₂N)₁₋ₓCₓ material layer that may be applied to an OTS selector device according to an embodiment of the present disclosure.

FIG. 15 is a graph illustrating the change in surface roughness (Rq) as a function of carbon content of a (W₂N)₁₋ₓCₓ material layer that may be applied to an OTS selector device according to an embodiment of the present disclosure.

FIG. 16 is a cross-sectional view illustrating the results of measuring the change in lifetime of an OTS selective element according to an embodiment of the present disclosure in response to an increase in the carbon content of a (W₂N)₁₋ₓCₓ material layer (electrode) applied to the OTS selective element.

FIG. 17 is a graph showing the average value of the device lifetime extracted from the repeated measurements in FIG. 16.

FIG. 18 is a cross-sectional view of a memory device with an OTS selector device according to an embodiment of the present disclosure.

FIG. 19 is a cross-sectional view illustrating a memory device having a cross-point array structure, according to an embodiment.

FIG. 20 is a graph showing a rough comparison of the manufacturing cost and performance of various memory devices.

### DETAILED DESCRIPTION

Some embodiments of the present disclosure are described in detail with reference to the accompanying drawings.

Such embodiments described below are provided to further illustrate some embodiments of the disclosure to those having ordinary skill in the art. Various embodiments of the disclosure are not intended to be limited by the following embodiments, and may be modified in various other ways.

The terms used in this specification are intended to describe some embodiments, and are not intended to limit various embodiments of the disclosure. Terms used herein in the singular form may include the plural form, unless the context clearly indicates otherwise. Furthermore, as used herein, the term “connected” is intended to mean not only that certain elements are directly connected, but also that they are indirectly connected by the interposition of one or more elements between them.

Further, when the present disclosure refers to a member being located “on” another member, this includes not only when a member is abutting another member, but also when there is at least one member between the two members. As used herein, the term “and/or” includes any one of the enumerated items and any combination of one or more of them. In addition, the terms “about,” “substantially,” and the like as used in the disclosure are intended to mean at or near the range of numbers or degrees, taking into account inherent manufacturing and material tolerances, and to prevent infringers from taking unfair advantage of the disclosure where precise or absolute numbers are stated, which are provided for the purpose of illustration. Throughout the specification and claims, a list of items prefaced by a phrase such as “at least one of” or “one or more of” or “one or both of” indicates an inclusive list. For example, a list of “at least one of A or B” and a list of “one or both of A and B” each indicate A, or B, or AB (i.e., A and B).

Some embodiments of the present disclosure are described in detail with reference to the accompanying drawings. The sizes or thicknesses of the areas or parts shown in the accompanying drawings may be somewhat exaggerated for clarity and ease of description. Throughout the detailed description, like reference numerals designate like components.

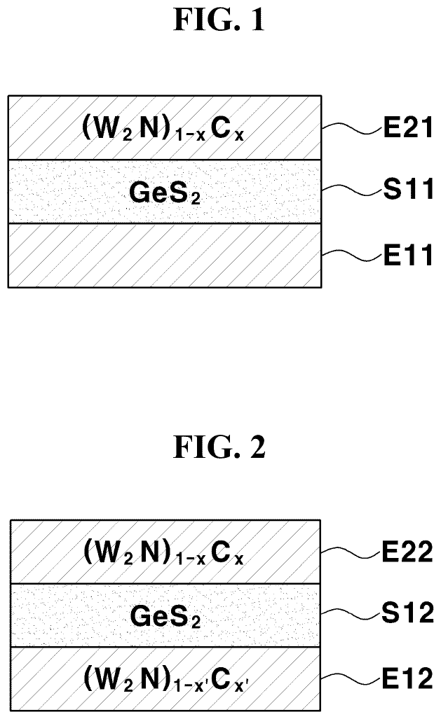

FIG. 1 is a cross-sectional view illustrating an ovonic threshold switch (OTS) selector device according to an embodiment of the present disclosure.

Referring to FIG. 1, an OTS selector device according to an embodiment of the present disclosure may include a first electrode (E11), a second electrode (E21) spaced apart from the first electrode (E11), and an ovonic threshold switch (OTS) material layer (S11) disposed between the first electrode (E11) and the second electrode (E21). The first electrode (E11) may be a lower electrode, and the second electrode (E21) may be an upper electrode. The OTS material layer (S11) may be referred to as a selector layer or a switching layer. The OTS material layer (S11) may be in direct contact with the upper surface of the first electrode (E11). The second electrode (E21) may be in direct contact with the top surface of the OTS material layer (S11). As a non-limiting example, the OTS selective element may have a metal-insulator-metal (MIM) structure or a similar structure.

The OTS material layer (S11) may be a thin film including a chalcogenide element. The OTS material layer (S11) may be a Ge-S thin film, wherein sulfur S is a chalcogenide element. As a specific example, the OTS material layer (S11) may include GeS₂ or may be formed of GeS₂. For example, the OTS material layer (S11) may be a thin film of GeS₂. The OTS material layer (S11) may be an amorphous chalcogenide thin film. The OTS material layer (S11) may be a dielectric layer. The OTS material layer (S11) may have a thickness of about 10 (e.g., 9.5 to 10.4 nm) to about 30 nm (e.g., 29.5 nm to 30.4 nm) or about 15 to about 20 nm, as a non-limiting example.

GeS₂ may have a relatively large bandgap (optical bandgap), characterized by low leakage current, but the driving voltage may be relatively high. The chalcogenide element S (sulfur) may have a relatively large bandgap and charge tunnelling may not be sufficient through GeS₂, and thus GeS₂ may have a relatively low leakage current. However, because of the relatively large bandgap, the driving voltage to the GeS₂ may be relatively high. In an embodiment of the present disclosure, the issues associated with GeS₂ having a relatively high driving voltage may be overcome by controlling the material and controlling the properties of the electrode (e.g., the second electrode (E21) in FIG. 1).

In addition, GeS₂ may have relatively good thermal stability. However, when GeS₂ is contacted with a common transition metal nitride, there may be a strong tendency for ionized transition metals (e.g., W, Ti, Ta, etc.) in the transition metal nitride to bond with chalcogenide elements in GeS₂ upon application of repeated operating voltages. The ionized transition metals may have a relatively high diffusivity, and as the ionized transition metals diffuse into the GeS₂ and combine with the chalcogenide elements, the physical and crystalline properties of the GeS₂ may change, and as a result, the durability of the GeS₂ and the durability of the device including the GeS₂ may deteriorate. In an embodiment of the present disclosure, by controlling the substance and controlling the physical properties of the electrode (e.g., the second electrode (E21) in FIG. 1), the diffusion of the substance from the electrode to the GeS₂ may be effectively prevented, and the durability of the GeS₂ and the durability of the device including the GeS₂ may be improved.

The second electrode (E21) may include a layer of tungsten carbonitride material that has a carbon content x. In some embodiments, the second electrode (E21) may include a (W₂N)₁₋ₓCₓ material or may be formed of a (W₂N)₁₋ₓCₓ material. For example, the second electrode (E21) may be a layer of (W₂N)₁₋ₓCₓ material. Here, x may be, for example, in the range of about 0.11 (e.g., 0.105 to 0.114) to about 0.25 (e.g., 0.245 to 0.254). The (W₂N)₁₋ₓCₓ material layer may have a material composition including W₂N and carbon (C) alloyed in a predetermined ratio. By controlling the content of carbon (C) in the (W₂N)₁₋ₓCₓ material layer to a predetermined ratio and controlling the crystal properties and physical properties of the (W₂N)₁₋ₓCₓ material layer, the driving voltage (i.e., threshold voltage) of the OTS selective element including the OTS material layer (S11), such as the GeS₂ layer, may be lowered and the durability may be improved. For example, when x is less than about 0.11, the (W₂N)₁₋ₓCₓ material layer may have a relatively large surface roughness of the layer, a relatively large interfacial trap density between layer and the OTS material layer, and/or undergo insufficient transition from a polycrystalline phase to an amorphous phase, resulting in an excessively high driving voltage of a device including the layer. When x is greater than about 0.25, the resistivity of the (W₂N)₁₋ₓCₓ material layer may become excessively large and/or further transition from a polycrystalline phase to an amorphous phase may no longer substantially take place. As a result, the power consumption of the OTS selective element may be minimized and the lifetime of the element may be increased.

According to an embodiment, the interface trap density between the (W₂N)₁₋ₓCₓ material layer and the OTS material layer (S11) may be in the range of about 8.76×10²⁰ cm⁻³ (e.g., 8.755×10²⁰ cm⁻³ to 8.764×10²⁰ cm⁻³) to about 11.61×10²⁰cm⁻³ (e.g., 11.605×10²⁰ cm⁻³ to 11.614×10²⁰ cm⁻³). The interface trap density may be the trap density of electrons at the interface between the (W₂N)₁₋ₓCₓ material layer and the OTS material layer (S11). Here, the OTS material layer (S11) may be, for example, a GeS₂ layer. Meanwhile, the (W₂N)₁₋ₓCₓ material layer may have a surface roughness (Rq) in the range of about 0.65 nm (e.g., 0.645 nm to 0.654 nm) to about 1.85 nm (e.g., 1.845 nm to 1.854 nm). The (W₂N)₁₋ₓCₓ material layer may be formed to have a relatively small surface roughness, and in connection therewith, the interfacial trap density between the (W₂N)₁₋ₓCₓ material layer and the OTS material layer (S11) may be reduced.

In the case of a W₂N thin film, it may be formed as a polycrystalline structure having a columnar structure. Therefore, when a W₂N thin film is formed on a bottom layer (selector layer), the W₂N thin film itself may have a columnar structure, resulting in voids between the bottom layer (selector layer) and the W₂N thin film and an increase in the interfacial trap density. In addition, the W₂N thin film may have a relatively large grain size and may have a relatively large surface roughness. If the interfacial trap density between the lower layer (selector layer) and the W₂N thin film is relatively high, the flow of electrons at the interface might not be smooth, and the driving voltage of the device may be relatively high.

In an embodiment of the present disclosure, a (W₂N)₁₋ₓCₓ material layer may be applied to an electrode. Here, carbon (C) has a relatively small atomic size, which may act to inhibit/prevent the (W₂N)₁₋ₓCₓ material layer from growing into a columnar structure. The (W₂N)₁₋ₓCₓ material layer may have a relatively small grain size or may include an amorphous phase. As the carbon (C) content increases, the (W₂N)₁₋ₓCₓ material layer may undergo a phase change from polycrystalline to amorphous. In addition, the (W₂N)₁₋ₓCₓ material layer may have a relatively small surface roughness. Thus, the interfacial trap density between the (W₂N)₁₋ₓCₓ material layer and the OTS material layer (S11) may be lowered, and the driving voltage (i.e., threshold voltage) of the OTS selective element according to such an embodiment may be lowered and the operating characteristics may be improved.

According to an embodiment, the (W₂N)₁₋ₓCₓ material layer may have a work function in the range of about 4.57 eV (e.g., 4.565 eV to 4.574 eV) to about 4.65 eV (e.g., 4.645 eV to 4.654 eV). The work function may increase as the content of carbon (C) in the (W₂N)₁₋ₓCₓ material layer increases. If the (W₂N)₁₋ₓCₓ material layer has a relatively large work function, the barrier height between the (W₂N)₁₋ₓCₓ material layer and the OTS material layer (S11) may decrease, facilitating tunneling of holes from the (W₂N)₁₋ₓCₓ material layer to the OTS material layer (S11). Thus, in this regard, the flow of current between the (W₂N)₁₋ₓCₓ material layer and the OTS material layer (S11) may be facilitated. By this effect, the driving voltage (i.e., the threshold voltage) of the OTS selective element may be lowered and the operating characteristics may be improved. Here, the OTS material layer (S11) may be, for example, a GeS₂layer, and the GeS₂layer may have p-type material properties.

According to an embodiment, the (W₂N)₁₋ₓCₓ material layer may have a density in the range of about 9.22 g/cm³ (e.g., 9.215 g/cm³ to 9.224 g/cm³) to about 11.08 g/cm³ (e.g., 11.075 g/cm³ to 11.084 g/cm³). As the content of carbon (C) in the (W₂N)₁₋ₓCₓ material layer increases, the density may increase. This may indicate that the crystalline properties and film quality of the (W₂N)₁₋ₓCₓ material layer change with the change of the carbon (C) content. On the other hand, the (W₂N)₁₋ₓCₓ material layer may have a resistivity in the range of about 1.37 mΩ/cm (e.g., 1.365 mΩ/cm to 1.374 mΩ/cm) to about 1.94 mΩ/cm (e.g., 1.935 mΩ/cm to 1.944 mΩ/cm). As the content of carbon (C) in the (W₂N)₁₋ₓCₓ material layer increases, the resistivity may increase somewhat. Therefore, it may be desirable to control the content of carbon (C) in the (W₂N)₁₋ₓCₓ material layer so that the content of carbon C does not become excessively high.

According to an embodiment, in the (W₂N)₁₋ₓCₓ material layer, x may range from about 0.11 to about 0.25. As a non-limiting example, the x may be in the range of about 0.16 (e.g., 0.155 to 0.164) to about 0.25 (e.g., 0.245 to 0.254). When the x is in the range of about 0.16 to about 0.25, the effect of reducing the drive voltage and improving the durability (lifetime) may be further enhanced.

According to an embodiment, the (W₂N)₁₋ₓCₓ material layer may include an amorphous phase. The (W₂N)₁₋ₓCₓ material layer including an amorphous phase or consisting largely of an amorphous phase may be advantageous in terms of reducing the drive voltage and improving the durability (lifetime) of the OTS selective element according to embodiments. However, in embodiments of the present disclosure, the (W₂N)₁₋ₓCₓ material layer may not include an amorphous phase, or may include both an amorphous phase and a crystalline phase.

The first electrode (E11) may have a different material composition than the second electrode (E21). For example, the first electrode (E11) may include at least one of W₂N, W, Ru, or TiN. However, the material of the first electrode (E11) is not limited to the foregoing. Any electrode material of a general selective element may be applicable as the material of the first electrode (E11). The positions of the first electrode (E11) and the second electrode (E21) may be reversed.

The first electrode (E11) may have a thickness of on the order of a few nm to several thousand nm, or on the order of tens of nm to several hundred nm. The second electrode (E21) may have a thickness of on the order of several nm to several thousand nm, or on the order of tens of nm to several hundred nm.

For operation of the OTS selection element according to the embodiment, for example, a positive voltage may be applied to the first electrode (E11) and a ground voltage may be applied to the second electrode (E21). Alternatively, a ground voltage may be applied to the first electrode (E11) and a positive voltage may be applied to the second electrode (E21). Alternatively, a first voltage may be applied to the first electrode (E11) and a second voltage different from the first voltage may be applied to the second electrode (E21), wherein the first and second voltages may not be ground voltages.

FIG. 2 is a cross-sectional view illustrating an OTS selection element according to another embodiment of the present disclosure.

Referring to FIG. 2, an OTS selective element according to this embodiment may include a first electrode (E12), a second electrode (E22) spaced apart from the first electrode (E12), and an OTS material layer (S12) disposed between the first electrode (E12) and the second electrode (E22). The OTS material layer (S12) and the second electrode (E22) in FIG. 2 may be the same as the OTS material layer (S11) and the second electrode (E21) described in FIG. 1, respectively. The second electrode (E22) may include a (W₂N)₁₋ₓCₓ material layer. Here, a first carbon content x may be, for example, in the range of about 0.11 to about 0.25.

In this embodiment, the first electrode (E12) may have substantially the same material composition. Thus, the first electrode (E12) may include a (W₂N)_{1-x′}C_{x′} material layer. Here, a second carbon content x′ may be in the range of, for example, about 0.11 to about 0.25. When the first electrode (E12) may have substantially the same material composition as the second electrode (E22), a difference between the first carbon content x and the second carbon content x′ may be not greater than 5%, 3%, or 1% of an average of the first and second carbon contents x and x′. All of the features described for the second electrode (E21) in FIG. 1 may be equally applied to the first electrode (E12) in FIG. 2. By applying an electrode including (W₂N)₁₋ₓCₓ and (W₂N)_{1-x′}C_{x′} material layers to both sides of the OTS material layer (S12) (e.g., the bottom surface and the top surface), the effects described above may be achieved and/or enhanced.

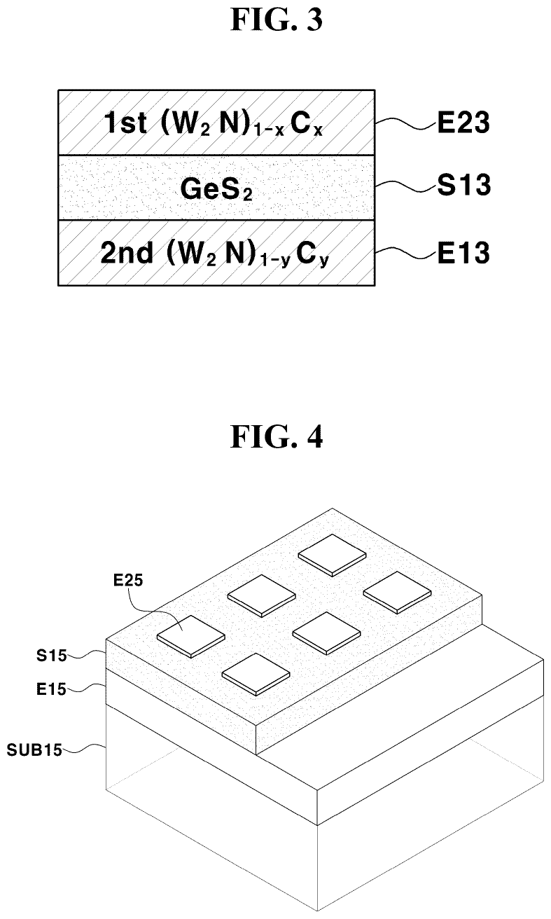

FIG. 3 is a cross-sectional view illustrating an OTS selection element according to another embodiment of the present disclosure.

Referring to FIG. 3, an OTS selective element according to this embodiment may include a first electrode (E13), a second electrode (E23) spaced apart from the first electrode (E13), and an OTS material layer (S13) disposed between the first electrode (E13) and the second electrode (E23). The OTS material layer (S13) and the second electrode (E23) may be the same as the OTS material layer (S11) and the second electrode (E21) described in FIG. 1, respectively. The second electrode (E23) may include a (W₂N)₁₋ₓCₓ material layer. Here, x may be, for example, in the range of about 0.11 to about 0.25.

In this embodiment, the (W₂N)₁₋ₓCₓ material layer of the second electrode (E23) may be a first (W₂N)₁₋ₓCₓ material layer, and the first electrode (E13) may include a second (W₂N)_{1-y}C_{y} material layer. The second electrode (E23) may include the first (W₂N)₁₋ₓCₓ material layer or may be composed of the first (W₂N)₁₋ₓCₓ material layer. The first electrode (E13) may include or consist of the second (W₂N)_{1-y}C_{y} material layer. In the second (W₂N)_{1-y}C_{y} material layer, y may be in the range of, for example, about 0.11 to about 0.25.

In some embodiments, the first (W₂N)₁₋ₓCₓ material layer and the second (W₂N)_{1-y}C_{y} material layer may have different carbon (C) contents. Specifically, the (W₂N)₁₋ₓCₓ material layer may have a first carbon content x and the (W₂N)_{1-y}C_{y} material layer may have a second carbon content y different from the first carbon content x. For example, a difference between the first carbon content x and the second carbon content y may be greater than 5%, 3%, or 1% of an average of the first and second carbon contents x and y. The carbon (C) content of one of the first (W₂N)₁₋ₓCₓ material layer and the second (W₂N)_{1-y}C_{y} material layer may be higher than the carbon (C) content of the other. In this case, an asymmetrical electrode structure may be formed on both sides thereof (e.g., a bottom surface and an upper surface) relative to the OTS material layer (S13), and the effect of precisely controlling and improving the operating characteristics of the OTS selective element may be obtained by considering the voltage application characteristics and current flow characteristics.

FIG. 4 is a cross-sectional view illustrating an OTS selection element manufactured in accordance with an embodiment of the present disclosure.

Referring to FIG. 4, the OTS selective element may include a first electrode (E15) disposed on a substrate SUB15, an OTS material layer (S15) disposed on the first electrode (E15), and a second electrode (E25) disposed on the OTS material layer (S15).

The substrate SUB15 may be an insulator substrate, and may be, as a non-limiting example, a glass substrate. The first electrode (E15) may be formed of W₂N, and may have a thickness of about 100 nm. The OTS material layer (S15) may be formed of GeS₂ and may have a thickness of about 15 nm. The second electrode (E25) may be formed of (W₂N)₁₋ₓCₓ and may have a thickness of about 30 nm. In the (W₂N)₁₋ₓCₓ, x may be in the range of about 0.11 to about 0.25. A portion (e.g., a portion of a top surface) of the first electrode (E15) might be exposed and not covered by the OTS material layer (S15). A plurality of second electrodes (E25) may be formed on the OTS material layer (S15) in a patterned form. However, the specific materials, thicknesses, shapes, etc. described in FIG. 4 are only examples and may vary according to embodiments.

A method of manufacturing an OTS selector device according to an embodiment of the present disclosure is described as follows.

A method of manufacturing an OTS selective element according to an embodiment of the present disclosure may include the steps of forming a first electrode, forming an OTS material layer including a chalcogenide element on the first electrode, and forming a second electrode on the OTS material layer.

The OTS material layer may be a Ge-S thin film. As a specific example, the OTS material layer may include GeS₂ or may be formed from GeS₂. In one example, the OTS material layer may be a GeS₂ thin film. The GeS₂ thin film may be formed, for example, using a magnetron sputtering process. The magnetron sputtering process may utilize radio frequency (RF) power, and the process temperature may be in the range of room temperature to a temperature of several hundred ° C., or room temperature to a temperature of several tens ° C.

The second electrode may include a (W₂N)₁₋ₓCₓ material layer, wherein x may be in the range of about 0.11 to about 0.25. The (W₂N)₁₋ₓCₓ material layer may be formed, for example, using a magnetron sputtering process. In this case, a tungsten target and an amorphous carbon target may be utilized, and the deposition may be carried out using nitrogen gas and argon gas. By adjusting the power applied to the amorphous carbon target or the power applied to each of the amorphous carbon target and the tungsten target, the carbon content in the deposited thin film may be controlled. The magnetron sputtering process may utilize direct current (DC) power, and the process temperature may be, for example, room temperature.

The first electrode may have a different material composition than the second electrode. In this case, the first electrode may include, as a non-limiting example, at least one of W₂N, W, Ru, or TiN. Alternatively, the first electrode may have substantially the same material composition as the second electrode, e.g., the first electrode may include a (W₂N)_{1-x′}C_{x′} material layer, wherein x′ may be in the range of about 0.11 to about 0.25. Alternatively, the second electrode may include a first (W₂N)₁₋ₓCₓ material layer, and the first electrode may include a second (W₂N)_{1-y}C_{y} material layer, wherein the first (W₂N)₁₋ₓCₓ material layer and the second (W₂N)_{1-y}C_{y} material layer may have different carbon (C) contents.

For example, if the first electrode is a W₂N thin film, the W₂N thin film may be formed, for example, using a magnetron sputtering process. In this case, a tungsten target may be utilized and the deposition may be carried out using nitrogen gas and argon gas. The magnetron sputtering process may utilize DC power, and the process temperature may be, for example, room temperature.

However, the specific processes, materials, and conditions described above for manufacturing the OTS selective element are only examples and may vary according to embodiments.

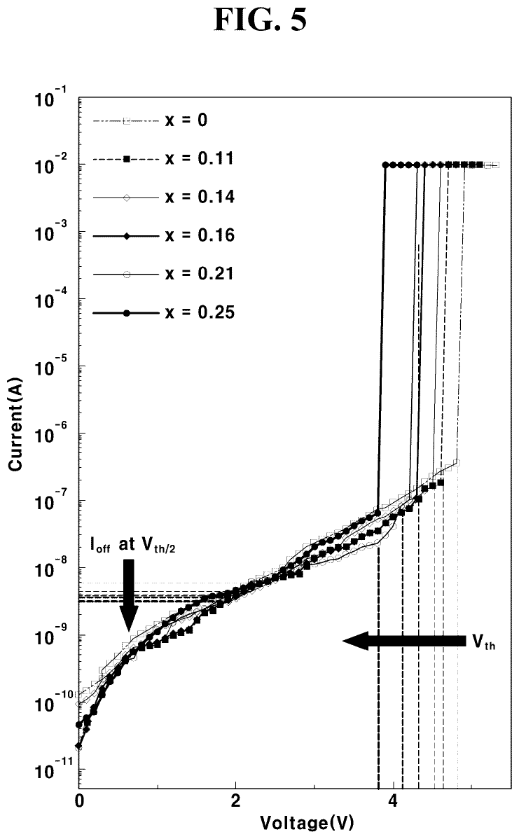

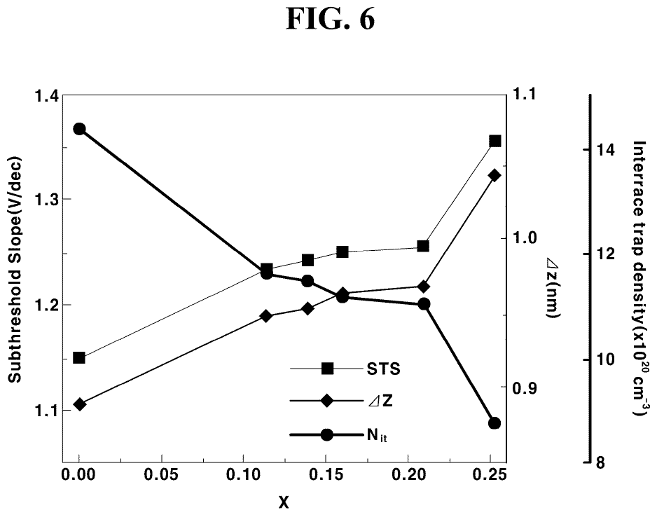

FIG. 5 is a graph showing the results of measuring the change in electrical properties of an OTS selective element according to an embodiment of the present disclosure in response to an increase in the carbon content of a (W₂N)₁₋ₓCₓ material layer applied as a second electrode in the OTS selective element. Here, the OTS selective element has the structure described in FIG. 4. FIG. 5 includes data for x=0, 0.11, 0.14, 0.16, 0.21, and 0.25. Here, the case of x=0 may correspond to a comparative example.

Referring to FIG. 5, as the carbon content of the (W₂N)₁₋ₓCₓ material layer applied as the second electrode increased, the driving voltage (i.e., threshold voltage Vₜₕ) of the OTS selector decreased. As the drive voltage decreases, the effect of reducing power consumption may be achieved. It may also be seen that the off-current (I_{off}) of the OTS selector decreases as the carbon content of the (W₂N)₁₋ₓCₓ material layer increases. As the off-current (I_{off}) decreases, the leakage current is reduced.

FIG. 6 is a graph showing the results of evaluating the changes in subthreshold slope (STS), distance between traps (Δz), and interface trap density (Nᵢₜ) with increasing carbon content of a (W₂N)₁₋ₓCₓ material layer applied as a second electrode in an OTS selective element according to an embodiment of the present disclosure. Here, the OTS selection element has the structure described in FIG. 4. FIG. 6 includes data for x=0, 0.11, 0.13, 0.16, 0.21, and 0.25. Here, the case of x=0 may correspond to a comparison example. The results in FIG. 6 may be extracted using the Poole-Frenkel model based on DC I-V measurement data. The STS value may be calculated based on the threshold voltage (Vₜₕ) value of 0.3 to 0.7 V.

Referring to FIG. 6, STS values were extracted as 1.1499, 1.2339, 1.2423, 1.2506, 1.2558, and 1.3554 for increasing carbon content. With increasing carbon content, the Δz values were calculated to be 0.890, 0.950, 0.955, 0.965, 0.970, and 1.045 nm. With increasing carbon content, the interfacial trap density Nᵢₜ decreased to 14.35×10²⁰, 11.61×10²⁰, 11.46×10²⁰, 11.02×10²⁰, and 8.76×10²⁰ cm⁻³. Here, the interfacial trap density Nᵢₜ may be the trap density of electrons at the interface between the OTS material layer and the (W₂N)₁₋ₓCₓ material layer. As the carbon content of the (W₂N)₁₋ₓCₓ material layer increases, the interfacial trap density Nᵢₜ may decrease, thereby lowering the driving voltage of the OTS selective element.

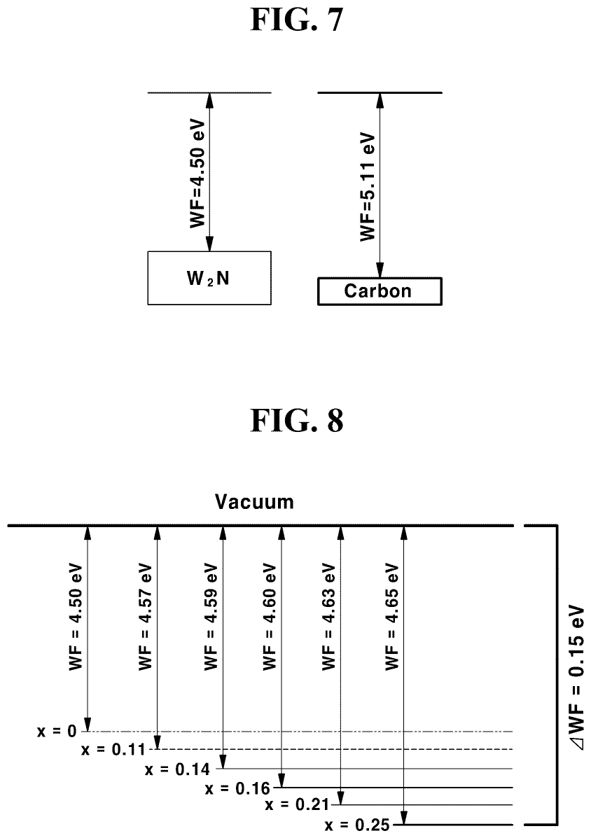

FIG. 7 shows the work function (WF) of a W₂N thin film and an amorphous carbon (a-C) thin film.

Referring to FIG. 7, a W₂N thin film may have a work function of 4.50 eV, while an a-C thin film may have a work function of 5.11 eV.

FIG. 8 is a plot showing the change in work function (WF) with increasing carbon content of a (W₂N)₁₋ₓCₓ material layer. FIG. 8 includes data for x=0, 0.11, 0.14, 0.16, 0.21, and 0.25. Here, the case of x=0 may correspond to a comparative example.

Referring to FIG. 8, the work functions increased to 4.57, 4.59, 4.60, 4.63, and 4.65 eV as the carbon content increased in the (W₂N)₁₋ₓCₓ material layer, with a total change in work function of 0.15 eV as x varied.

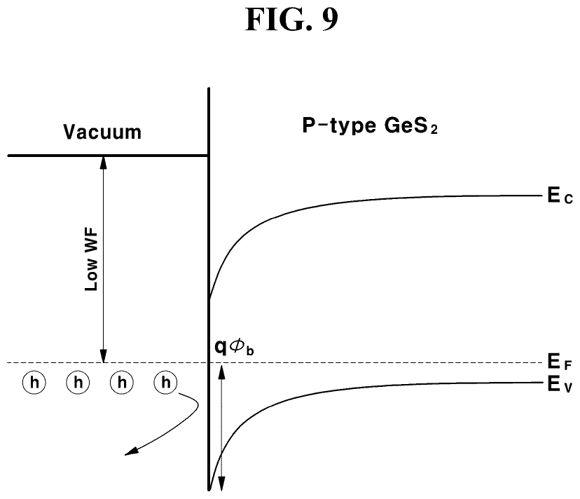

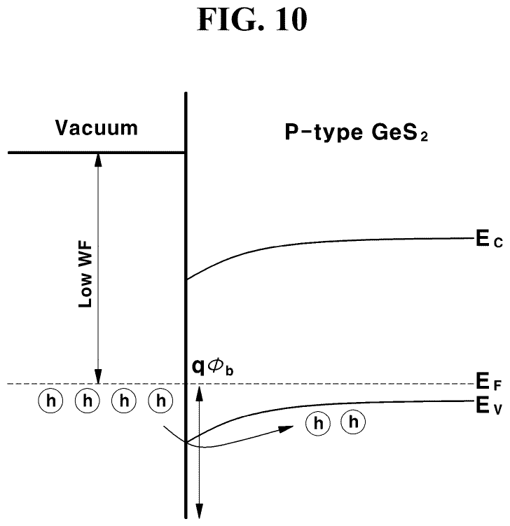

FIGS. 9 and 10 are diagrams illustrating the change in energy band diagrams as the work function of the electrode changes for interconnected electrodes and GeS₂ thin films. FIG. 9 shows the case where the work function of the electrode is relatively small, and FIG. 10 shows the case where the work function of the electrode is relatively large. In FIGS. 9 and 10, E_{C} denotes the lowest energy level in the conduction band, E_{V} denotes the highest energy level in the valence band, and E_{F} denotes the Fermi energy level.

Referring to FIGS. 9 and 10, the OTS material layer (selector layer) may be a GeS₂ thin film, and the GeS₂ thin film may have p-type material properties. Thus, as the work function of the electrode increases, the barrier height between the electrode and the GeS₂ thin film may decrease, facilitating tunneling of holes from the electrode to the GeS₂ thin film. In embodiments of the present disclosure, if the (W₂N)₁₋ₓCₓ material layer has a relatively large work function, the barrier height between the (W₂N)₁₋ₓCₓ material layer and the OTS material layer may be reduced. Thus, in this regard, the flow of current between the (W₂N)₁₋ₓCₓ material layer and the OTS material layer may be facilitated. Due to this effect, the driving voltage (i.e., threshold voltage) of the OTS selective element may be lowered and the operating characteristics may be improved.

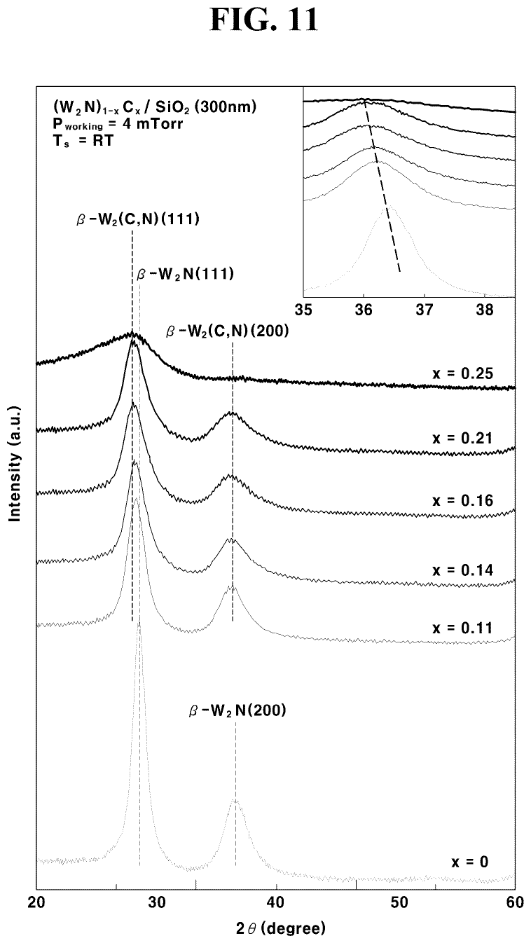

FIG. 11 is an X-ray diffraction (XRD) graph showing changes in crystalline properties with changes in carbon content of a (W₂N)₁₋ₓCₓ material layer that may be applied to an OTS selective element, according to an embodiment of the present disclosure. FIG. 11 shows the results of XRD analysis performed on the (W₂N)₁₋ₓCₓ material layer after forming a (W₂N)₁₋ₓCₓ material layer on a SiO₂ layer (thickness: 300 nm). x was varied as 0, 0.11, 0.14, 0.16, 0.21, and 0.25. The inset in FIG. 11 is a magnified view of the β-W₂ (C, N) (111) peak.

Referring to FIG. 11, it may be seen that as the carbon content in the (W₂N)₁₋ₓCₓ material layer increases, the crystallinity of the (W₂N)₁₋ₓCₓ material layer changes from polycrystalline to amorphous. For x=0.25, the (W₂N)₁₋ₓCₓ material layer may be nearly or substantially amorphous.

In the case of a W₂N thin film, it may be formed as a polycrystalline structure having a columnar structure. Therefore, when a W₂N thin film is formed on a bottom layer (selector layer), the W₂N thin film itself may have a columnar structure, resulting in voids between the bottom layer (selector layer) and the W₂N thin film and an increase in the interfacial trap density. In addition, the W₂N thin film may have a relatively large grain size and may have a relatively large surface roughness. If the interfacial trap density between the lower layer (selector layer) and the W₂N thin film is relatively high, the flow of electrons at the interface may not be smooth, and the driving voltage of the device may be relatively high.

In an embodiment of the present disclosure, a (W₂N)₁₋ₓCₓ material layer may be applied to an electrode. Here, carbon (C) has a relatively small atomic size, which may act to inhibit/prevent the (W₂N)₁₋ₓCₓ material layer from growing into a columnar structure. The (W₂N)₁₋ₓCₓ material layer may have a relatively small grain size or may include an amorphous phase. As the carbon (C) content increases, the (W₂N)₁₋ₓCₓ material layer may undergo a phase change from polycrystalline to amorphous. In addition, the (W₂N)₁₋ₓCₓ material layer may have a relatively small surface roughness. Thus, the interfacial trap density between the (W₂N)₁₋ₓCₓ material layer and the OTS material layer may be lowered, and the driving voltage (i.e., threshold voltage) of the OTS selective element according to such an embodiment may be lowered and the operating characteristics may be improved.

Referring to FIG. 11, without wishing to be limited by theory, it may be seen that as x increases, the β-W₂ (C, N) (111) peak is gradually shifted to the left, which may be a result of the compressive stress applied to the thin film as the carbon content increases. It may also be seen that as x increases, the peak gradually softens, and for x=0.25, the peak is almost flat. This might indicate that the (W₂N)₁₋ₓCₓ material layer becomes amorphous when x is 0.25.

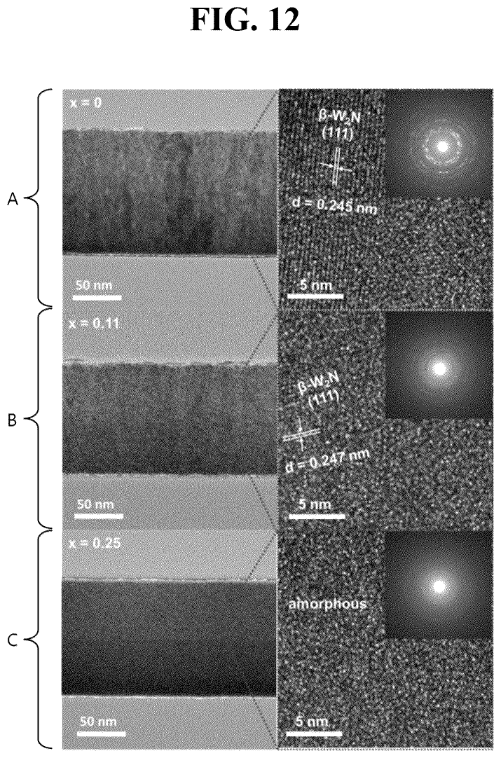

FIG. 12 is a transmission electron microscope (TEM) analysis image illustrating changes in crystalline properties with changes in carbon content of a (W₂N)₁₋ₓCₓ material layer that may be applied to an OTS selector device according to embodiments of the present disclosure. In FIG. 12, area A is for x=0, area B is for x=0.11, and area C is for x=0.25.

Referring to FIG. 12, it may be seen that as the carbon content in the (W₂N)₁₋ₓCₓ material layer increases, the crystallinity of the (W₂N)₁₋ₓCₓ material layer changes from polycrystalline to amorphous. For x=0.25, the (W₂N)₁₋ₓCₓ material layer may be nearly or substantially amorphous.

From the analysis of FIGS. 11 and 12, it may be seen that the microstructure change and crystalline property change due to the change in carbon content of the (W₂N)₁₋ₓCₓ material layer. According to embodiments of the present disclosure, microstructure changes and corresponding performance changes of OTS selective devices may be adjusted using (W₂N)₁₋ₓCₓ material layers of different compositions with different windows.

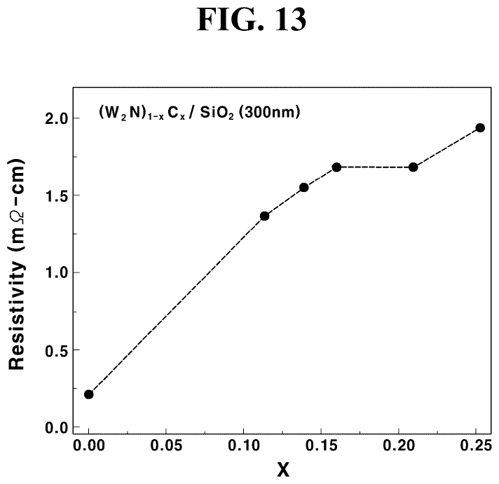

FIG. 13 is a graph illustrating the change in resistivity with a change in carbon content of a (W₂N)₁₋ₓCₓ material layer that may be applied to an OTS selective element according to an embodiment of the present disclosure. FIG. 13 shows the results of measuring the resistivity of a (W₂N)₁₋ₓCₓ material layer after forming a (W₂N)₁₋ₓCₓ material layer on a SiO₂ layer (thickness: 300 nm). Here, x was varied as 0, 0.11, 0.13, 0.16, 0.21, and 0.25.

Referring to FIG. 13, for a carbon-free (i.e., x=0) W₂N material layer (thin film), the resistivity is found to be 0.211 mΩ⋅cm. As the carbon content increased to 11 at %, 13 at %, 16 at %, 21 at %, and 25 at %, the resistivity of the (W₂N)₁₋ₓCₓ material layer increased to 1.367, 1.552, 1.684, 1.685, and 1.940 mΩ⋅cm.

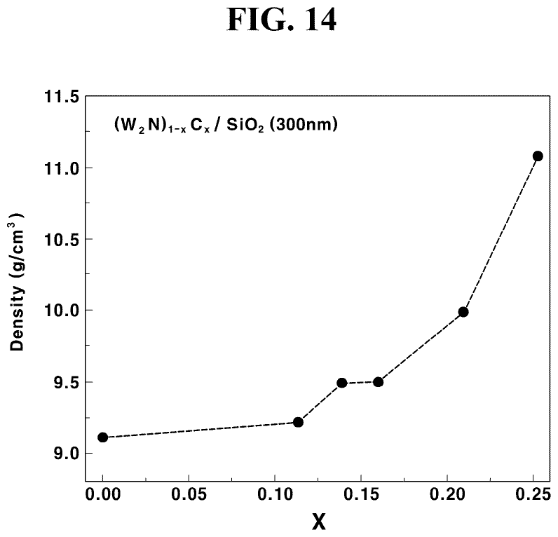

FIG. 14 is a graph illustrating the density variation with changing carbon content of a (W₂N)₁₋ₓCₓ material layer that may be applied to an OTS selective element, according to an embodiment of the present disclosure. FIG. 14 shows the results of measuring the density of a (W₂N)₁₋ₓCₓ material layer after forming a (W₂N)₁₋ₓCₓ material layer on a SiO₂ layer (thickness: 300 nm). Here, x was varied as 0, 0.11, 0.13, 0.16, 0.21, and 0.25.

Referring to FIG. 14, for a carbon-free (i.e., x=0) W₂N material layer (thin film), the density was found to be 9.11 g/cm³. As the carbon content increased to 11 at %, 13 at %, 16 at %, 21 at %, and 25 at %, the density of the (W₂N)₁₋ₓCₓ material layer increased to 9.22, 9.49, 9.50, 9.99, and 11.08 g/cm³.

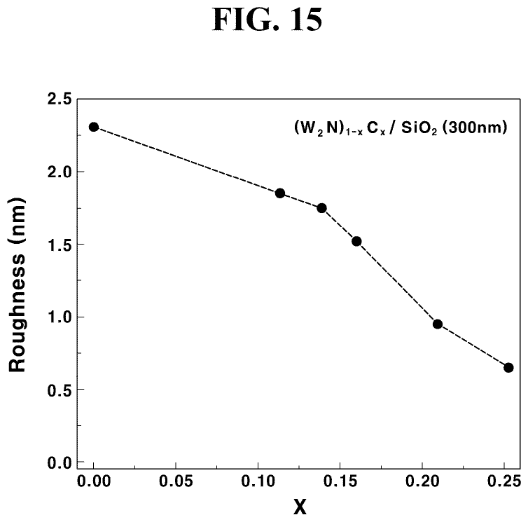

FIG. 15 is a graph showing the variation of surface roughness (Rq) with the variation of carbon content of a (W₂N)₁₋ₓCₓ material layer that may be applied to an OTS selective element, according to an embodiment of the present disclosure. FIG. 15 shows the results of measuring the surface roughness (Rq) of a (W₂N)₁₋ₓCₓ material layer after forming a (W₂N)₁₋ₓCₓ material layer on a SiO₂ layer (thickness: 300 nm). Here, x was varied as 0, 0.11, 0.13, 0.16, 0.21, and 0.25.

Referring to FIG. 15, for a carbon-free (i.e., x=0) W₂N material layer (thin film), the surface roughness was found to be 2.31 nm. As the carbon content increased to 11 at %, 13 at %, 16 at %, 21 at %, and 25 at %, the surface roughness of the (W₂N)₁₋ₓCₓ material layer decreased to 1.85, 1.75, 1.52, 0.95, and 0.65 nm.

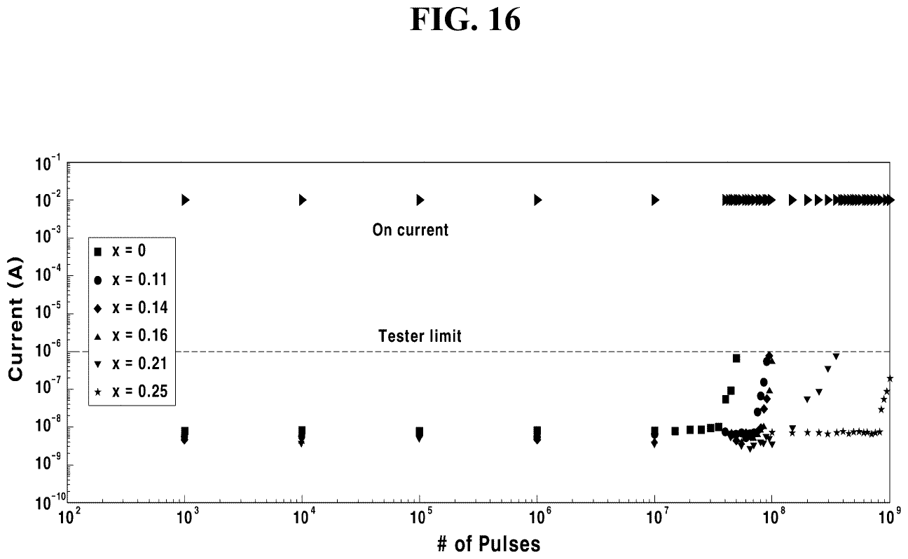

FIG. 16 is a cross-sectional view showing the results of measuring the change in the lifetime of the OTS selective element in response to an increase in the carbon content of a (W₂N)₁₋ₓCₓ material layer (electrode) applied to an OTS selective element, according to an embodiment of the present disclosure. Here, the OTS selective element has the structure described in FIG. 4. FIG. 16 includes data for x=0, 0.11, 0.14, 0.16, 0.21, and 0.25. Here, the case of x=0 may correspond to a comparative example.

Referring to FIG. 16, switching was repeatedly performed by applying repeated AC voltage pulses to the OTS selective element, and the off-current of the element was measured to evaluate the performance (lifetime/durability) of the element based on the point at which the off-current increases. As the carbon content increased, the device lifetime of the OTS-selected devices increased.

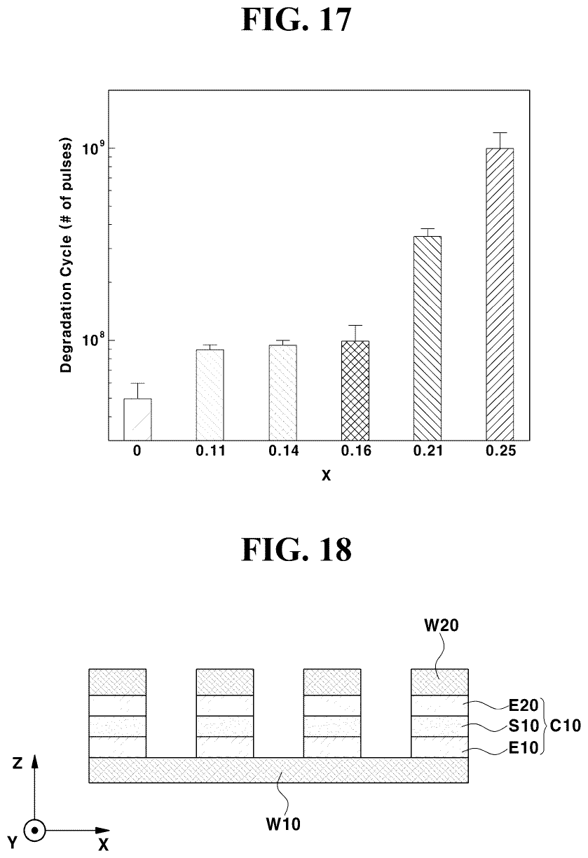

FIG. 17 is a graph showing the average value of the device lifetime estimated from the repeated measurements in FIG. 16.

Referring to FIG. 17, for a carbon-free (i.e., x=0) W₂N material layer (thin film), the device was stable up to 5.0×10⁷ pulses. As the carbon content increased, the lifetime increased and performance improved up to 9.0×10⁷, 9.5×10⁷, 1.0×10⁸, 3.5×10⁸, and 1.0×10⁹ pulses.

The OTS selection element (or OTS selector device) according to embodiments of the present disclosure described above may be applied to a memory element. The memory element may be a non-volatile memory element. A memory device may include such an OTS selector device, and the memory device may have, for example, a cross-point structure. The memory device may have a cross-point array structure, e.g., a crossbar array structure. In addition, the memory device may have a selector-only memory (SOM) structure. The SOM structure is a selector layer that simultaneously implements the roles of memory and switch with itself, and might not use separate memory elements.

FIG. 18 is a cross-sectional view of a memory device with an OTS selection element (or OTS selector device) according to an embodiment of the present disclosure.

Referring to FIG. 18, a memory device according to an embodiment may include a plurality of first wires (W10) extending side-by-side in a first direction (e.g., X-axis direction) and a plurality of second wires (W20) extending side-by-side in a second direction (e.g., Y-axis direction) that intersects the first direction. While a single first wiring (W10) is shown here, in practice, a plurality of first wiring (W10) may be spaced apart from each other in the second direction (e.g., in the Y-axis direction). The plurality of second wires (W20) may each extend in a direction orthogonal to the plurality of first wires (W10).

The memory element may include a memory cell (C10) disposed at each of the intersections between the plurality of first wires (W10) and the plurality of second wires (W20). The memory cell (C10) may have a configuration of an OTS selection element according to the embodiments described with reference to FIGS. 1 to 3 and the like. Thus, the memory cell (C10) may include a first electrode (E10), an OTS material layer (S10), and a second electrode (E20). The first electrode (E10), the OTS material layer (S10), and the second electrode (E20) may correspond to each of the first electrodes (E11), (E12), and (E13), each of the OTS material layers (S11), (S12), and (S13), and each of the second electrodes (E21), (E22), and (E23) described in FIGS. 1 to 3, respectively. The OTS material layer (S10) may act as a selector layer (switching layer) and simultaneously act as a memory layer. The memory cell (C10) may not utilize a separate memory element other than the OTS material layer (S10). Thus, the memory element may have a selector-only memory (SOM) structure.

In some cases, a portion of the first wiring (W10) may take over the role of the first electrode (E10), in which case the portion of the first wiring (W10) may be considered the first electrode. Similarly, a portion of the second wiring (W20) may take the role of the second electrode (E20), in which case the portion of the second wiring (W20) may be considered the second electrode.

In the case of a memory device with a SOM structure, an OTS material layer (selector layer) may simultaneously realize the role of a memory and a switch. In this regard, the material applied to the OTS material layer may be relatively limited, and the driving voltage may be relatively limited depending on the band gap or composition ratio of the OTS material layer. In an embodiment of the present disclosure, a memory device having a SOM structure with a controlled drive voltage may be realized by controlling the material and controlling the properties of the electrodes in contact with the OTS material layer.

It is possible to control the drive voltage by controlling the thickness of the selector layer, but increasing the thickness may increase power consumption, and decreasing the thickness may increase leakage current due to tunneling. In other words, there may be a trade-off in controlling the drive voltage by controlling the thickness. In an embodiment of the present disclosure, by controlling the driving voltage and controlling the leakage current through material control and physical property control of the electrode, the above trade-off problem may be overcome and an SOM device with desirable performance may be realized.

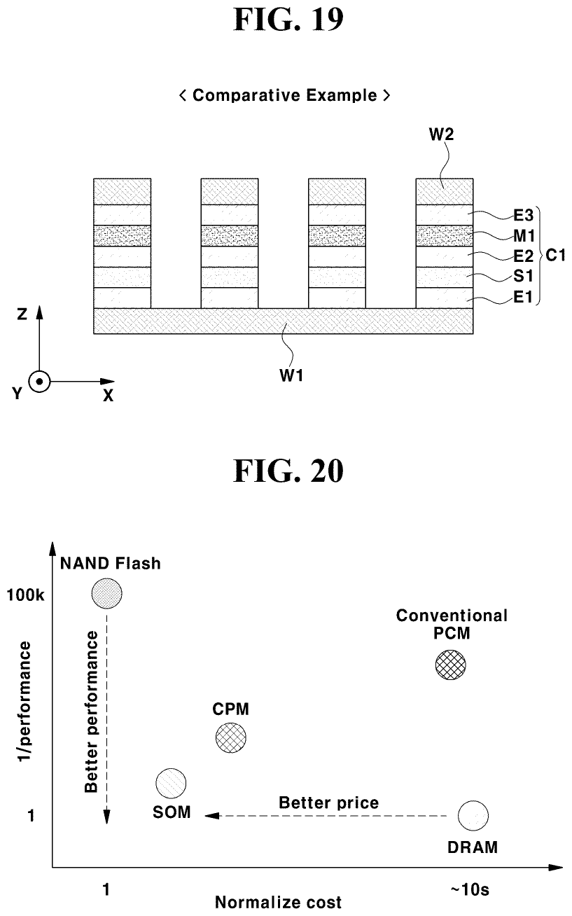

FIG. 19 is a cross-sectional view illustrating a comparative example of a memory device having a cross-point array structure.

Referring to FIG. 19, the comparative example of a memory device may have a general intersection point array structure. The memory device according to the comparative example may include a plurality of first wires (W1) extending side-by-side in a first direction (X-axis direction) and a plurality of second wires (W2) extending side-by-side in a second direction (Y-axis direction) that intersects the first direction). The memory device according to the comparative example may include a memory cell (C1) disposed at each of the intersections between the plurality of first wires (W1) and the plurality of second wires (W2). The memory cell (C1) may include a selection element and a memory element. The memory cell (C1) may include a first electrode (E1), a selector layer (S1), a second electrode (E2), a memory layer (M1), and a third electrode (E3) stacked in sequence on the first wiring (W1). The first electrode (E1), the selector layer (S1), and the second electrode (E2) may constitute a single selection element. The memory layer (M1) may be a memory element, for example, a phase change memory layer.

When the memory cell (C1) includes both a selection element and a memory element, as shown in FIG. 19, the structure is complex, difficult to manufacture, and may be disadvantageous in terms of improving integration compared to the SOM structure illustrated in FIG. 18.

FIG. 20 is a graph showing a rough comparison of the manufacturing cost and performance of various memory devices. FIG. 20 shows the results of a comparative evaluation of selector-only memory (SOM), cross-point memory (CPM), phase-change memory (PCM), NAND Flash, and dynamic random access memory (DRAM). Here, CPM corresponds to a typical CPM device that is not a SOM, and PCM corresponds to a conventional PCM device.

Referring to FIG. 20, it may be seen that the SOM exhibits superior performance while being inexpensive to manufacture compared to a conventional CPM device, a conventional PCM device, and the like. Thus, a memory device according to an embodiment having a SOM structure as described in FIG. 18 may have significant advantages in terms of manufacturing cost and performance.

According to embodiments of the present disclosure, it is possible to realize an OTS selector device with an electrode material that may complement and resolve the disadvantages of an OTS material layer including a chalcogenide element. Furthermore, according to embodiments of the present disclosure, it is possible to realize an OTS selector device including an electrode material and an OTS material layer bonded thereto that may be applied to a highly integrated device and maintain desirable performance even in repeated operation. Furthermore, according to embodiments of the present disclosure, by applying the above OTS selective element (or selector device), a memory device may be realized that may improve performance and integration while lowering manufacturing costs and simplifying manufacturing processes. According to an embodiment, by preparing a (W₂N)₁₋ₓCₓ material film as an electrode of an OTS selective element and bonding it to an OTS material layer including a chalcogenide element (e.g., a GeS₂ layer), an OTS selective element may be implemented that may increase the work function of the electrode and control the interface trap density between the electrode and the OTS material layer, thereby reducing the drive voltage and minimizing power consumption. Furthermore, by effectively suppressing the diffusion of the electrode material even in repeated operation, an OTS selective element having desirable durability/stability and long lifetime may be realized. By applying the OTS selector device according to an embodiment, a memory device (e.g., non-volatile memory device) having a selector-only memory (SOM) structure, for example, may be implemented, thereby improving the performance and integration of the memory element while lowering the manufacturing cost and simplifying the manufacturing process.

Although the present disclosure describes some embodiments of the present disclosure, these embodiments are not intended to limit the scope of various embodiments of the present disclosure. In addition to the embodiments disclosed herein, various modifications based on the technical ideas of the present disclosure may be possible. For example, OTS selector devices according to embodiments of the present disclosure are applicable not only to SOM structures, but also to non-SOM junction memory device structures or other memory device structures. The scope of various embodiments the disclosure is therefore not limited by the above-described embodiments, but rather by the technical ideas recited in the claims of the patent.

What is claimed is:

1. An ovonic threshold switch (OTS) selector device, the device comprising:
a first electrode;
a second electrode spaced apart from the first electrode, the second electrode comprising a (W₂N)₁₋ₓCₓ material layer, wherein x is in a range of about 0.11 to about 0.25; and
an ovonic threshold switch (OTS) material layer disposed between the first electrode and the second electrode, the OTS material layer comprising a chalcogenide element.

2. The device of claim 1, wherein an interface trap density between the (W₂N)₁₋ₓCₓ material layer and the OTS material layer is in a range of about 8.76×10²⁰ cm⁻³ to about 11.61×10²⁰cm⁻³.

3. The device of claim 1, wherein the (W₂N)₁₋ₓCₓ material layer has a work function in a range of about 4.57 eV to about 4.65 eV.

4. The device of claim 1, wherein the (W₂N)₁₋ₓCₓ material layer has a surface roughness (Rq) in a range of about 0.65 nm to about 1.85 nm.

5. The device of claim 1, wherein the (W₂N)₁₋ₓCₓ material layer has a density in a range of about 9.22 g/cm³ to about 11.08 g/cm³.

6. The device of claim 1, wherein the (W₂N)₁₋ₓCₓ material layer has a resistivity in a range of about 1.37 mΩ⋅cm to about 1.94 mΩ⋅cm.

7. The device of claim 1, where x is in the range of about 0.16 to about 0.25.

8. The device of claim 1, wherein the (W₂N)₁₋ₓCₓ material layer comprises an amorphous phase.

9. The device of claim 1, wherein the OTS material layer comprises GeS₂.

10. The device of claim 1, wherein the first electrode has a different material composition than the second electrode.

11. The device of claim 1, wherein the first electrode comprises at least one of W₂N, W, Ru, or TiN.

12. The device of claim 1, wherein the first electrode has substantially the same material composition as the second electrode.

13. The device of claim 1, wherein the first electrode comprises a (W₂N)_{1-y}C_{y} material layer.

14. The device of claim 13, wherein the (W₂N)₁₋ₓCₓ material layer has a first carbon content x and the (W₂N)_{1-y}C_{y} material layer has a second carbon content y different from the first carbon content x.

15. A memory device comprising the OTS selector device according to claim 1.

16. The device of claim 15, wherein the memory device has a selector-only memory (SOM) structure.

17. The device of claim 15, wherein the memory device has a cross-point structure.

18. An ovonic threshold switch (OTS) selector device, the device comprising:
a first electrode;
a second electrode spaced apart from the first electrode, the second electrode comprising a tungsten carbonitride material layer that has a carbon content x, wherein x is in a range of about 0.11 to about 0.25; and
an ovonic threshold switch (OTS) material layer disposed between the first electrode and the second electrode, the OTS material layer comprising a chalcogenide element.

19. The device of claim 18, wherein the tungsten carbonitride material layer is a (W₂N)₁₋ₓCₓ material layer.

20. The device of claim 19, wherein the first electrode has substantially the same material composition as the second electrode.
